(19) United States
(12) Patent Application Publication
(10) Pub. No.: US 2007/0009002 A1
(43) Pub. Date: Jan. 11, 2007

(54) Semiconductor laser array beam transformer/equalizer

(76) Inventors: Baiming Guo, Morganville, NJ (US); Thomas Stakelon, North Hollywood, CA (US); Jeffrey E. Ungar, Valley Village, CA (US)

Correspondence Address: IRELL & MANELLA LLP, 840 NEWPORT CENTER DRIVE, SUITE 400, NEWPORT BEACH, CA, 92660, US

(21) Appl. No.: 11/175,699

(22) Filed: Jul. 6, 2005

(51) Int. Cl. H01S 5/00

(52) U.S. Cl. 372/50.12

(57) ABSTRACT

An optical system that improves and equalizes the beam quality of a semiconductor laser array. The semiconductor lasers are arranged along a first axis, and the second axis has a higher beam quality than the first axis. The system includes a high-efficiency optical device that transforms light beams emitted from the lasers into any desired re-arranged shapes, such as a column along a second axis, or a circular arrangement.

### CROSS REFERENCE TO RELATED APPLICATIONS

This application claims priority to provisional Application No. 60/585,044 filed on Jul. 2, 2004.

### BACKGROUND OF THE INVENTION

1. Field of the Invention

The subject matter disclosed generally relates to the field of semiconductor lasers.

2. Background Information

Semiconductor laser diode arrays are efficient and reliable sources of high power coherent light for various applications including pumping of solid-state lasers, medical, defense, and materials processing. Arrays of individually addressed lasers are also used for data communications.

High power laser arrays are typically fabricated by combining a plurality of laser “bars”. Each laser bar consists of a single semiconductor chip incorporating a plurality of edge-emitting laser stripes. Edge emitting lasers tend to emit in elliptically shaped laser beams.

FIG. 1 shows an elliptical shaped laser beam 2 emitted from a conventional edge emitting laser diode 4. The laser beam 2 has what is referred to as a slow Axis and a fast Axis. The beam quality 2 is defined by the beam width multiplied by the divergence of the beam, in slow axis and fast axis direction respectively. Beam quality is improved by lowering the beam width and/or the beam divergence. For most laser diodes the divergence is greater in the fast axis than the slow axis. The beam width (emitter width) is much greater along the slow axis than the beam width in the fast axis. The product of the beam width times the divergence is thus larger for the slow axis than the fast axis. Consequently, the beam quality along the slow axis is worse than the quality of the beam in the fast axis. It would be desirable to improve the beam quality in the slow axis and equalize the beam quality between slow axis and fast axis with a low cost reliable optical device.

### BRIEF SUMMARY OF THE INVENTION

An optical system that includes an array of semiconductor lasers, an optical device, and other optics. The semiconductor lasers are arranged along a first axis. The high-efficiency optical device transforms light beams emitted by the lasers into any arrangement with equalized beam quality between both axes, such as a column arrangement along a second axis or a circular arrangement.

### BRIEF DESCRIPTION OF THE DRAWINGS

FIGS. 1 is an illustration showing a light beam emitted by an edge emitting laser diode of the prior art;

FIG. 2 is an illustration of an embodiment of an optical system which reshapes the output of a laser array into a vertically stacked array;

FIG. 3 is an illustration of an alternate embodiment of the optical system which reshapes the beam into a circular array.

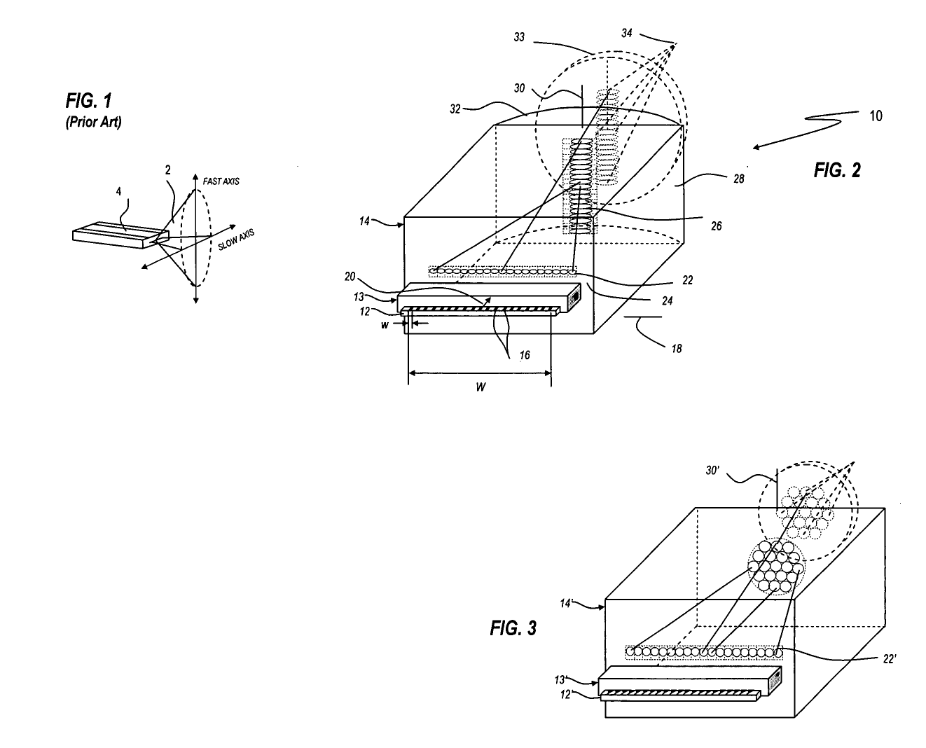

### DETAILED DESCRIPTION

Disclosed is an optical system that improves and equalizes the beam quality of a semiconductor laser array. The semiconductor lasers are arranged along a first axis. The system includes a high-efficiency optical device that transforms light beams emitted from the lasers into a column along a second axis to achieve similar beam quality between the two axes, while before the transformation, the second axis has a higher beam quality than the first axis.

Referring to the drawings more specifically by reference numbers, FIG. 2 shows an embodiment of an optical system 10. The optical system 10 includes a semiconductor laser array 12 and an optical device 14. The array 12 may be a bar that contains a plurality of edge emitting laser diodes 16, as is known in the art. The laser diodes 16 may be arranged along a first axis 18. The first axis 18 may be an axis of relatively poor beam quality. This axis 18 is also referred to as the slow axis.

Each laser diode emits a beam of light 20. Because of the edge emitting nature of the laser diodes 16 each diverging beam may have an elliptical shape. Then, the elliptical shaped beams 20 are collimated through collimating optics 13, such as a fast axis collimator and then, the beams are transformed by the optical device 14. Additionally, although the array 12 is shown as being separated from the collimating optics 13 and the optical device 14, the device 14 may be contiguous, or in close proximity, to the optics 13 and the array 12.

The optical device 14 may include a plurality of first diffraction gratings 22 on a first surface 24 and a plurality of second diffraction gratings 26 on a second surface 28. The first diffraction gratings 22 diffract each light beam 20 from the laser diodes 16 through the collimating optics 13 into a column that extends along a second axis 30. The optical device 14 has a corresponding grating for each laser diode so that the light is diffracted at a desired angle to align all of the beams along the second axis 30. It is desirable to construct the first gratings 22 so that the outer beams of the array are diffracted toward the middle of the column, and the middle beams of the array are diffracted toward the outer portions of the column. In this manner the lengths of the light paths from the first gratings 22 to the column are approximately equal for all beams.

Beam quality can be defined by the divergence times the width of the beam. Beam quality improves inversely with the product of these two parameters. The array initially has a beam width of W defined by the total width of all the beams. The column on the second axis 30 has beam width w which is the width of one diode's beam. By reducing the beam width the optical device improves the beam quality.

For the conventional bars, the beam quality along the second axis is much better than that along the first axis. Consequently, re-arranging the light beams between the two axes equalizes the overall beam quality by increasing the beam quality in the first axis and decreasing that in the second axis. The following is an example of this concept.

Suppose a 10-mm bar having 19 emitters with emitter width of 0.15 mm and divergence of 200 mrad in the first axis direction. The beam quality is the product of these two numbers and the number of emitters in the row, or, 19×200 mrad×0.15 mm=19×30 mm-mrad. The beam divergence along the second axis is 1000 mrad and emitter width of about 1 micron, and the beam quality along this axis, with only one emitter in this axis, is 1×1000 mrad×0.001 mm=1 mm-mrad. By considering beam quality degradation by the fast axis collimating lens, the beam quality is therefore approximately 1.6 mm-mrad.

The optical device 14 transforms the beams to align along the second axis on the second surface 28 of the device 14. The beam quality along the first axis at the second surface can be the same as one of the emitters, 30 mm-mrad. The beam quality along the second axis becomes 19×1.6 mm-mrad, around 30 mm-mrad, similar to the first axis'. This is an improvement in the beam quality along the first axis of about 19:1. The beam height along the second axis is increased by about 19 times, resulting in a beam quality decreased to about 19×1.6 mm-mrad, about 30 mm-mrad. Although the beam quality along the fast axis was degraded, the beam quality values along both axes are about equal. In general the optical device can be used to re-arrange the beams along an axis that has higher beam quality than the axis along which the beams are emitted from the laser diode array.

The second gratings 26 may diffract the light beams into substantially straight and parallel paths out of the device 14. The optical device 14 may include a cylindrical lens 32 that collimates the light beams at the output of the device 14 for the first axis beam collimation in a simply way.

A focusing optics 33 may be placed at the output of the device 14 to focus the beam to a much smaller spot at focal plane 34 than that without the device 14, for focused beam or fiber coupled beam applications.

FIG. 3 shows an alternate embodiment wherein the optical device 14′ has different diffraction gratings 22′ to transform a one dimensional array of light beams of laser diodes with similar beam quality in its fast and slow axis into a circular arrangement 30′. In general the optical device 14 or 14′, may diffract that light beams into any number of columns, and any shapes of arrangement.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

What is claimed is:

1. An optical system, comprising:
an array of semiconductor lasers that each emit a beam of light, said semiconductor lasers being arranged along a first axis; and,
an optical device that transforms said beams of light into at least one column along a second axis.

2. The system of claim 1, wherein said optical device includes a plurality of first diffraction gratings that diffract said beams of light into said column.

3. The system of claim 1, wherein said light beams are shaped as a slit.

4. The system of claim 1, wherein said second axis has a higher beam quality than said first axis.

5. The system of claim 1, wherein said optical device includes a collimator.

6. The system of claim 2, wherein said optical device includes a plurality of second gratings that straighten a path of each beam of light.

7. The system of claim 1, wherein said array of semiconductor lasers is a two dimensional array.

8. An optical system, comprising:
an array of semiconductor lasers that each emit a beam of light, said semiconductor lasers being arranged along a first axis; and,
optical transformation means for transforming said beams of light into at least one column along a second axis.

9. The system of claim 8, wherein said optical transformation means includes gratings to diffract said beams of light.

10. The system of claim 8, wherein said light beams are shaped as a slit.

11. The system of claim 8, wherein said second axis has a higher beam quality than said first axis.

12. The system of claim 8, wherein said optical device includes a collimator.

13. The system of claim 8, wherein said array of semiconductor lasers is a two dimensional array.

14. A method for operating an array of semiconductor lasers, comprising:
emitting a plurality of light beams from an array of semiconductor lasers arranged along a first axis; and,
transforming the laser beams into a column along a second axis.

15. The method of claim 14, wherein the light beams are transformed by a plurality of first diffraction gratings of an optical device.

16. The method of claim 15, wherein the light beams are further diffracted by a plurality of second diffraction gratings.

17. The method of claim 14, wherein the light beams are each shaped as a slit.

18. The method of claim 14, wherein the second axis has a higher beam quality than the first axis.
